(19) United States
(12) Patent Application Publication
(10) Pub. No.: US 2009/0311160 A1
(43) Pub. Date: Dec. 17, 2009

(54) Silicon single crystal and method of producing the same

(76) Inventors: Yasuhiro Saito, Tokyo (JP); Nobumitsu Takase, Tokyo (JP)

Correspondence Address: CLARK & BRODY, 1090 VERMONT AVENUE, NW, SUITE 250, WASHINGTON, DC, 20005, US

(21) Appl. No.: 12/457,421

(22) Filed: Jun. 10, 2009

(30) Foreign Application Priority Data
Jun. 12, 2008 (JP) 2008-154478

(51) Int. Cl. C01B 33/02; C30B 15/22

(52) U.S. Cl. 423/348; 117/35

(57) ABSTRACT

The present invention provides a silicon single crystal comprising a seed crystal, a narrowed portion whose diameter decreases, and at its lower end, a neck portion, wherein in a front projection view, the contour of the narrowed portion is located inside the straight line connecting the contour of the lower end of the seed crystal to the contour of the upper end of the neck portion, and the contour of the neck portion is made to be a tangent at the lower end of the narrowed portion. At this time, the length L of the narrowed portion in a pulling direction and the difference d between the radius of the seed crystal and the radius of the narrowed portion relative to the diameter W of the seed crystal is appropriately adjusted and further the contour of the narrowed portion is desirably formed with any one of parabolas, circular arcs and elliptic arcs. Configuring the contour of the narrowed portion in this manner makes it possible to remove dislocations from the neck portion with a high success rate, shorten a pulling time of the silicon single crystal and improve the dislocation free ratio.

### BACKGROUND OF THE INVENTION

1. Field of the Invention

The present invention relates to a silicon single crystal including a narrowed portion at the lower end of a seed crystal and a neck portion at the lower end of the narrowed portion, produced by the Czochralski method (hereinafter, referred to as the “CZ method”). More particularly, the invention relates to a silicon single crystal comprising a narrowed portion shape capable of removing dislocations from the neck portion with a high success rate without lengthening the narrowed portion and the neck portion and a method of producing the silicon single crystal.

2. Description of the Related Art

Various methods are available for manufacturing silicon single crystals used for semiconductor substrates. Of these, the Czochralski method is widely adopted.

FIGS. 1A and 1B are schematic diagrams of the cross-sectional configuration of main parts of a pulling apparatus suitable for implementing a method of pulling a silicon single crystal by the CZ method. FIG. 1A is an overall view and FIG. 1B is an enlarged view of its part (the part surrounded with the broken-line circle in FIG. 1A).

The outside appearance of the pulling apparatus includes a chamber, not-shown, and a crucible 1 is placed in its central portion. As shown in FIG. 1A, the crucible 1 has a dual structure which comprises: a quartz crucible 1a in a cylindrical form with a closed-end, the quartz crucible being an inner container; and a graphite crucible 1b in a cylindrical form with a closed-end cylindrical, the graphite crucible being made of graphite and being an exterior container adapted to support the outside of the quartz crucible 1a.

The crucible 1 is fixed to the top end of a supporting shaft 6 which can rotate, ascend and/or descend, and outside the crucible 1 is disposed a resistance-heating heater 2 in a generally concentric pattern. Semiconductor silicon raw materials of a predetermined weight charged into the crucible 1 is melted to form a melt 3.

On the central axis of the crucible 1 filled with the melt 3 is disposed a pulling line (shaft or wire, collectively called a “pulling line”) 5 that rotates at a predetermined speed in the same or reverse direction relative to the crucible on the same axis as the supporting shaft 6. At the lower end of the pulling axis 5 is held a seed crystal 7.

When a silicon single crystal is pulled with such a pulling apparatus, semiconductor silicon single crystal raw materials are charged into the quartz crucible 1a, and the materials are melted with the heater 2 disposed around the crucible 1 in a reduced-pressure, inert gas atmosphere. Thereafter, the seed crystal 7 that is retained at the lower end of the pulling line 5 is contacted with the surface of the formed melt 3 and the so-called “thermal equilibration of seed crystal” is performed. The temperature of the melt 3 immediately after the silicon single crystal raw materials has been melted is higher than the melting point of silicon and locally largely varies, and its deviation becomes extremely large as the whole of the melt 3.

Typically, the “thermal equilibration of seed crystal” is performed in a predetermined time after melting of silicon single crystal raw materials. In this “thermal equilibration of seed crystal,” the surface temperature of the melt 3 is estimated by observing the meniscus shape of the contact interface when the seed crystal 7 is contacted with the melt 3, the electric current of the heater 2 is controlled on the basis of the estimation, the heat input to the melt 3 is adjusted, and the surface temperature of the melt 3 is stabilized.

After the completion of the “thermal equilibration of seed crystal” and the stabilization of the melt 3 held within the quartz crucible 1a, the seed crystal 7 is immersed in the melt 3. Then, the pulling line 5 is pulled upward to grow a single crystal on the lower end face of the seed crystal 7, while rotating the crucible 1 and the pulling line 5.

In that case, as shown in FIG. 1B, after passing a necking step in which the diameter of the seed crystal 7 is reduced by adjusting the pulling speed to form a narrowed portion 8 and a neck portion 9 thereafter, the crystal diameter is gradually increased by reducing the pulling speed to form a shoulder 10, followed by the procedure where a constant diameter portion (body portion) 11 is pulled. After the constant diameter portion 11 reaches a predetermined length, the crystal diameter is gradually decreased and one campaign of pulling is completed by separating its topmost portion from the melt 3 to obtain a predetermined-shape silicon single crystal 4.

Typically, the ratio of the weight of the pulled dislocation-free crystal to the charge weight of the silicon single crystal raw materials is called a dislocation free ratio. This dislocation free ratio becomes an indicator that shows the efficiency of pulling operation or the capability of a pulling apparatus. Improvement of the value is very important in producing a silicon single crystal.

The improvement of the dislocation free ratio requires the prevention of dislocations generated in the constant diameter portion 11 (body portion) in the step of pulling a silicon single crystal. The above-mentioned necking step (this step is also called a “seed crystal narrowing step”) is an indispensable step for removing high density dislocations introduced into a seed crystal by the heat shock when the seed crystal is contacted with a silicon melt. Here, reliable removal of the dislocations is important. This method of removing the dislocations is called the Dash method.

Conventionally, various methods have been proposed about the removal of dislocations of a silicon single crystal at the time of pulling. For example, Japanese Patent No. 2822904 proposes a method of producing a silicon single crystal in which the length of a tapered narrowed portion following a seed crystal is kept 2.5 to 15 times the diameter of the seed crystal, the diameter of a long-length, substantially cylindrical narrowed portion following the tapered narrowed portion is set to be 0.09 to 0.9 times the diameter of the seed crystal, the fluctuation range of the diameter of the straight narrowed portion is kept within 1 mm, and its length is kept in the range of 200 mm to 600 mm.

Japanese Patent No. 2940461 proposes a method of forming a tapered portion in which the narrowing angle formed by a radial direction and a tapered direction of a tapered portion is smaller than the angle in which the crystal growth orientation of a single crystal makes with the crystal dislocation face in a method of growing a single crystal that involves gradually decreasing the radial direction of a crystal based on a seed crystal to form a tapered portion, pulling the crystal with a given radial dimension, and then gradually increasing the radial dimension of the growth end, i.e., a method of performing seed narrowing with the angle of the tapered portion being equal to or larger than the propagation angle of dislocations.

The method proposed in the above-described Japanese Patent No.2822904 involves making the narrowed portion formed very long, so that it takes time to form the narrowed portion and consequently a total the time of pulling the entire single crystal becomes enormous, with the result of low productivity of a single crystal. In addition, in the method proposed in Japanese Patent No. 2940461(2) as above, the tapered portion is suddenly thinned during seed narrowing, whereby the thickness of the tapered portion likely becomes thinner than a target thickness in an actual production of a silicon single crystal to thereby lose strength to possibly drop off the silicon single crystal.

### SUMMARY OF THE INVENTION

The present invention has been made in view of the above problems during pulling of a silicon single crystal, and an object thereof is to provide a silicon single crystal comprising a narrowed portion shape having less likelihood of dropping off the silicon single crystal and a method of producing the single crystal, capable of removing dislocations from the neck portion with a high success rate without lengthening the narrowed portion and the neck portion when the silicon single crystal is produced.

To achieve the above object, the present inventors focuses on an effective contribution of the shape of the narrowed portion to the improvement of the above-mentioned dislocation free ratio, and repeated pulling of a silicon single crystal and investigated the shape of the narrowed portion and the situations of the occurrence of dislocations.

FIG. 2 is a front projection view that shows the contour of a narrowed portion and its vicinity which is formed during pulling by the CZ method. As illustrated in FIG. 2, a narrowed portion 8 of a length L in the pulling direction is formed from the lower end of a seed crystal 7 of a diameter W, with pulling of the seed crystal 7. The diameter of this narrowed portion 8 is set such that the depth from the diameter W becomes larger as the narrowed portion goes farther away from the seed crystal 7. In addition, a neck portion 9 is made to grow from the lower end of the narrowed portion 8. The neck portion 9 has a cylinder shape having a substantially same radius as the radius of the lower end of the narrowed portion 8 and is grown such that the difference between the radius of the seed crystal 7 and the radius of the neck portion 9 is d. Next, the shoulder 10 to be pulled in which the diameter is rapidly increased is formed.

Table 1 summarizes the shapes of the narrowed portion divided into four kinds of shapes A to D by classifying the seed crystal diameter W and the relation between the length L of the narrowed portion in the pulling direction and the radius difference d of the both.

TABLE 1

| Shape | L/W | d/W |
|---|---|---|
| A | L/W ≦ 2.50 | 0.156 ≦ d/W |
| B | 2.50 < L/W ≦ 6.25 | 0.156 ≦ d/W |
| C | 6.25 < L/W | 0.156 ≦ d/W |
| D | L/W ≦ 2.50 | 0.125 ≦ d/W |

Each contour of shapes A, B and C is located inside the straight line K (indicated with a broken line in the drawing) connecting the contour of the lower end of the seed crystal 7 to the contour of the upper end of the neck portion 9 in the above front projection view of FIG. 2. The contour of the neck portion 9 is the tangent of the lower end of the narrowed portion 8, i.e., the contour of narrowed portion 8 in the upper end of the neck portion 9. On account of this, the contour of the narrowed portion 8 and the contour of the neck portion 9 are configured to come in contact with each other in the upper end of the neck portion 9.

Thus, in shapes A, B and C shown in Table 1, in case the diameter W of the seed crystal 7 is the same, the length L of the narrowed portion 8 in the pulling direction is the shortest in shape A and longest in shape C.

In shape D indicated in Table 1, its contour is located outside the straight line K connecting the contour of the lower end of the seed crystal 7 to the contour of the upper end of the neck portion 9 in the above front projection view of FIG. 2.

FIG. 3 is a partial front projection view of the the narrowed portion and its vicinity in which the coordinate axes are set for the description of an embodiment of the narrowed portion contour. In the coordinate axes in FIG. 3, the coordinate center is set on the contour of the upper end of the neck portion 9, x axis is parallel to the pulling direction which is set to be a negative direction, and y axis is perpendicular to the pulling direction and the outward direction from the centerline of the neck portion 9 is set to be a positive direction.

When the coordinate axes indicated in FIG. 3 is set, any of the parabola, the circular arc and the elliptic arc can be applied to the contours of narrowed portions 8 of shapes A, B and C indicated with a solid line so long as the contours are positioned inside the straight line K connecting the contour of the lower end of the seed crystal 7 to the upper end of the neck portion 9.

First, when the contour of the narrowed portion is formed with a parabora, the contour may be represented by the function expressed by equation (3) below:

y=ax² (a=d/L², −L≦x≦0, 0≦y≦d) (3)

Next, when the contour of the narrowed portion is formed with a circular arc, the contour may be represented by the function expressed by equation (4) below:

x²/b²+(y−b)²/b²=1 (b=(L²+d²)/b²d, −L≦x≦0, 0≦y≦d) (4)

Further, when the contour of the narrowed portion is formed with an elliptic arc, the contour may be represented by the function expressed by equation (5) below:

x²/p²+(y−q)²/q²=1 (L²/p²+(d−q)²/q²=1, p≧L, q≧d, −L≦x≦0, 0≦y≦d) (5)

wherein, when p=q, the contour is a circular arc expressed by equation (4) in equation (5).

Table 2 shows the results in which silicon single crystals were pulled 15 times for each of four kinds of shapes A to D in the narrowed portion shape. Here, each contour of the narrowed portion of shapes A, B and C was set to be a parabola shown by equation (3) above.

In Table 2, “Dash-neck success” refers to the case where dislocations did not occur until the completion of silicon single crystal pulling and the case where the constant diameter portion (body portion) length exceeded 300 mm to cause dislocations. In addition, “Dash-neck failure” refers to the case where dislocations occurred during the formation of the shoulder or when the constant diameter portion (body portion) length is 300 mm or less.

TABLE 2

| | Dash-neck | Dash-neck | |
|---|---|---|---|
| Shape | success | failure | Total |
| A | 13 | 2 | 15 |
| B | 10 | 5 | 15 |
| C | 9 | 6 | 15 |
| D | 4 | 11 | 15 |
| Total | 36 | 24 | 60 |

The results in Table 2 show that when the shapes of the narrowed portion are shapes A, B and C, dislocations hardly occur as compared with shape D, i.e., a shape in which the contour of the narrowed portion is located outside the straight line connecting the contour of the lower end of the seed crystal to the upper end of the neck portion. In the case where the shapes of the narrowed portion are shapes A, B and C, it is shown that dislocations hardly occur in the order of shape A, shape B to shape C. This tendency is confirmed to occur also in the case where the contour of the front projection view of the narrowed portion has a circular arc expressed by equation (4) above and in the case where the contour has an elliptic arc expressed by equation (5) above.

The present invention has been made based on such findings and the gist thereof includes the silicon single crystals (1) to (3) as below and the methods of producing the silicon single crystals (4) and (5).

(1) A silicon single crystal comprising: a seed crystal; a narrowed portion being set at the lower end of a seed crystal and its diameter decreasing with distance from the seed crystal; a neck portion at the lower end of the narrowed portion; and a shoulder that makes contact with the lower end of the neck portion, characterized in that, when viewed on a front projection, the contour of the narrowed portion is located inside straight line which connects the contour of the lower end of the seed crystal to the contour of the upper end of the neck portion, and the contour of the neck portion is made to be a tangent at the lower end of the narrowed portion.
(2) In the above silicon single crystal (1) and in the contour of the narrowed portion that is front projected, the length L of the narrowed portion in a pulling direction and the difference d between the radius of the seed crystal and the radius of the lower end of the narrowed portion relative to the diameter W of the seed crystal desirably satisfy the relations of equations (1) and (2) below:

L/W≦2.5 (1)

d/W≧0.156 (2)

(3) In the above silicon single crystals (1) and (2), the contour of the narrowed portion can be formed with any one of parabolas, circular arcs and elliptic arcs.

In this case, when the contour of the narrowed portion is formed with a parabola, the contour can be expressed by equation (3) as below:

y=ax2 (a=d/L², −L≦x≦0, 0≦y≦d) (3)

Moreover, when the contour is formed with a circular arc, the contour of the narrowed portion can be expressed by equation (4) as below:

x²/b²+(y−b)²/b²=1 (b=(L²+d²)/2d, −L≦x≦0, 0≦y≦d) (4)

In addition, when the contour is formed with an elliptic arc, the contour of the narrowed portion can be expressed by equation (5) as below:

x²/p²+(y−q)²/q²=1 (L²/p²+(d−q)²/q²=1, p≧L, q≧d, −L≦x≦0, 0≦y≦d) (5)

(4) A method of producing a silicon single crystal which comprises forming: a narrowed portion in which the diameter decreases with distance from the seed crystal, by contacting a seed crystal with a melt of silicon raw material and pulling the seed crystal to make contact with the lower end of the seed crystal; a neck portion at the lower end of the narrowed portion; and a shoulder at the lower end of the neck portion, characterized in that, when the narrowed portion is formed, in a front projection view of the narrowed portion, the contour of the narrowed portion is located inside straight line which connects the contour of the lower end of the seed crystal to the contour of the upper end of the neck portion, and the tangent of the contour of the narrowed portion at its lower end constitutes the contour of the neck portion.
(5) In the above method of producing a silicon single crystal of (4), in a front projection view of the narrowed portion, the length L of the narrowed portion in a pulling direction and the difference d between the radius of the seed crystal and the radius of the narrowed portion at its lower end desirably satisfy the relations of equations (1) and (2) as above in terms of the diameter W of the seed crystal.

In addition, in the above methods of producing a silicon single crystal of (4) and (5), the contour of the above narrowed portion can be formed with any one of parabolas, circular arcs and elliptic arcs, expressed by the above equations (3), (4) and (5) respectively.

In a silicon single crystal of the present invention, the contour of the narrowed portion in a front projection view is positioned inside straight line connecting the contour of the lower end of the seed crystal to the contour of the upper end of the neck portion, and configured to be a parabola, a circular arc or an elliptic arc, for example.

Such features can efficiently remove dislocations from the neck portion without lengthening the narrowed portion and the neck portion as well as can shorten the time required for pulling a silicon single crystal and improve the dislocation free ratio of a resulting silicon single crystal when a silicon single crystal is produced.

As a result, in the manufacturing method of the present invention, the productivity of a silicon single crystal can be improved, and the likelihood of dropping of a silicon single crystal can be reduced, which can also improve the productivity of a silicon single crystal.

### BRIEF DESCRIPTION OF THE DRAWINGS

FIGS. 1A and 1B are diagrams schematically illustrating configurations of main parts of a pulling apparatus suitable for implementing a method of pulling a silicon single crystal by the CZ method, in which FIG. 1A is an overall view and FIG. 1B is an enlarged view of the indicated portion.

FIG. 2 is a partial front projection view of a narrowed portion and its vicinity, which is formed during pulling by the CZ method.

FIG. 3 is a partial front projection view of the narrowed portion and its vicinity in which coordinate axes are set for description of an embodiment of the contour.

FIG. 4 is a diagram indicating the results of “success rate of Dash-neck” of a pulling test in Example 1.

FIGS. 5A and 5B are diagrams indicating observation results by means of X-ray topographs (XRT) observing the behavior of dislocations by vertically splitting the narrowed portion.

### DETAILED DESCRIPTION OF THE PREFERRED EMBODIMENTS

A silicon single crystal of the present invention comprises; as shown in FIG. 2, a seed crystal 7; a narrowed portion 8 being provided at the lower end of the seed crystal 7 and increasing in diameter with distance from the seed crystal 7; a neck portion 9 at the lower end of the narrowed portion 8; and a shoulder 10 at the lower end of the neck portion 9, and it is configured so that, in a front projection view, the contour of the narrowed portion 8 is provided inside the straight line K that connects the contour of the lower end of the seed crystal 7 to the contour of the upper end of the neck portion 9 and that the contour of the neck portion 9 is made to be a tangent at the lower end of the narrowed portion 8.

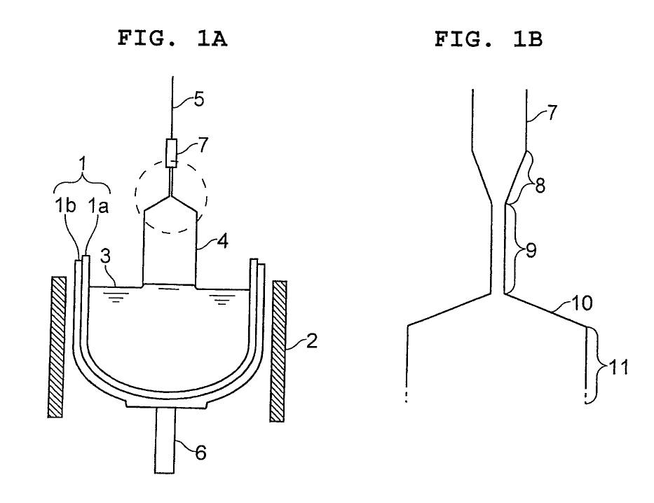

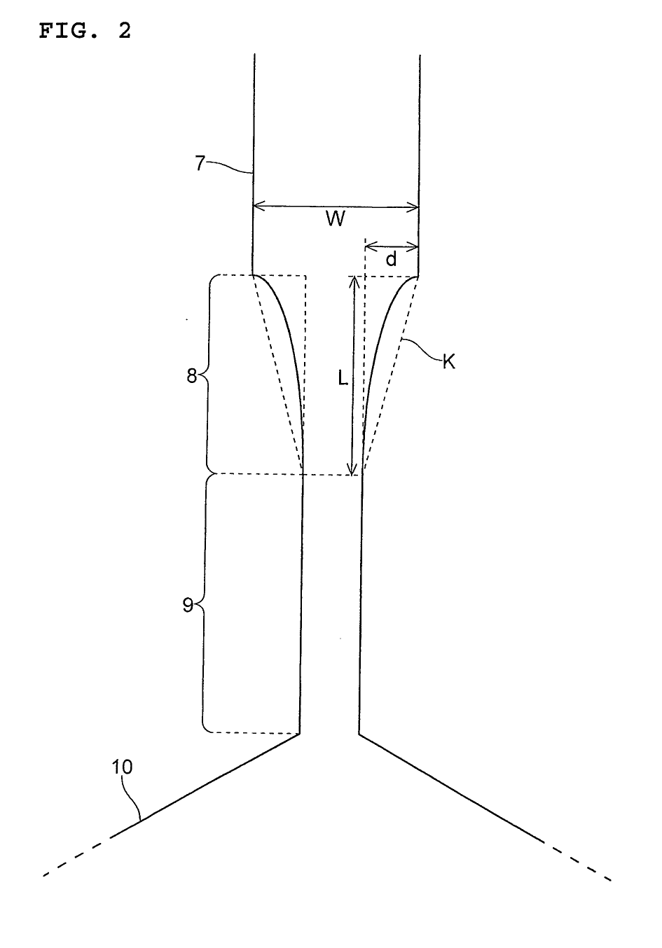

In addition, a method of producing a silicon single crystal of the present invention involves contacting the seed crystal 7 with a melt 3 and pulling the crystal by means of a pulling apparatus shown in FIG. 1, to thereby form the seed crystal 7, the narrowed portion 8 having the above-described shape, the neck portion 9 and the shoulder 10, as shown in FIG. 2.

In the silicon single crystal of the present invention and the manufacturing method thereof, the reason why the configuration is made so that “in a front projection view, the contour of the narrowed portion 8 is provided inside the straight line K that connects the contour of the lower end of the seed crystal 7 to the contour of the upper end of the neck portion 9” is that the propagation angle of dislocations is 54.7°, for example, when a seed crystal of a crystal orientation of [100] is used, and if the narrowing angle of narrowed portion 8 is made steep, dislocations are likely to be removed in the narrowed portion 8.

In the silicon single crystal of the present invention and the manufacturing method thereof, the relations of equations (1) and (2) as below are desirably satisfied from the results indicated in Table 2 above, as a measure of readily removing dislocations in the narrowed portion 8 by suddenly changing the narrowing angle of the narrowed portion 8.

L/W≦2.5 (1)

d/W≧0.156 (2)

Satisfying the relation of equation (1) makes it possible to avoid gradually approximating the shape of the narrowed portion to a target shape. Additionally, the satisfaction of the relation of equation (2) can assure the narrowing amount in terms of the diameter W of the seed crystal and sufficiently and suddenly change the narrowing angle of the narrowed portion 8.

At this occasion, the difference d between the radius of the seed crystal and the radius of the lower end of the narrowed portion is not limited so long as the relation of equation (2) is met. However, as the radius of the lower end of the narrowed portion, i.e., the size of the neck portion unnecessarily narrows, the silicon single crystal may drop off. Therefore, while the relation of equation (2) is met, the diameter of the neck portion is desirably 3 mm or more. Moreover, the difference d between the radius of the seed crystal and the radius of the lower end of the narrowed portion desirably satisfies the range d<(W−3)/2.

In the silicon single crystal of the present invention and the manufacturing method thereof, the contour of the narrowed portion can be formed with any one of parabolas expressed by equation (3) below, circular arcs expressed by equation (4) below and elliptic arcs expressed by equation (5) below in order to suddenly change the narrowing angle of the narrowed portion 8 to thereby easily remove dislocations in the narrowed portion 8. In any case, dislocations can be removed in the narrowed portion by suddenly changing the narrowing angle of the narrowed portion 8 to form a dislocation-free silicon single crystal on the lower end of the neck portion.

y=ax² (a=d/L², −L≦x≦0, 0≦y≦d) (3)

x²/b²+(y−b)²/b²=1 (b=(L²+d²)/2d, −L≦x≦0, 0≦y≦d) (4)

x²/p²+(y−q)²/q²=1 (L²/p²+(d−q)²/q²=1, p≧L, q≧d, −L≦x≦0, 0≦y≦d) (5)

In the silicon single crystal of the present invention and the manufacturing method thereof, the temperature of the melt is suitably set higher than the conventional temperature at the time of “thermal equilibration of seed crystal” for forming the contour shape of a specified narrowed portion.

In other words, “thermal equilibration of seed crystal” means the operation in which, by observation of the meniscus shape of the contact interface when the crystal is contacted with the melt, for example, the protrusion of the crystal habit line, the temperature of the melt surface is estimated, and then on the basis of this, the heater power (electric power) is controlled, the heat input into the melt is adjusted, and the melt surface temperature is stabilized.

After this thermal equilibration of seed crystal, the heater power is increased to thereby set the temperature of the melt surface to be slightly high. As a result, solidification to the pulling speed during the formation of the narrowed portion is delayed, so that the contour of the narrowed portion can be positioned inside the straight line connecting the contour of the lower end of the seed crystal to the contour of the upper end of the neck portion.

As described above, the variation of workability generated by pulling batch difference or operator's proficiency can be restrained by specifying the contour shape of the narrowed portion to be targeted, whereby crystal pulling can be stably performed under the same conditions even in any pulling operations.

### EXAMPLES

### Example 1

Repeated pulling tests were performed using two existing pulling apparatuses No.1 and No.2 to confirm the effect of contour shapes of the narrowed portion on non-dislocation in a pulling process of a single crystal in the silicon single crystal of the present invention. Twenty silicon single crystal pulling processes were carried out for each pulling apparatus.

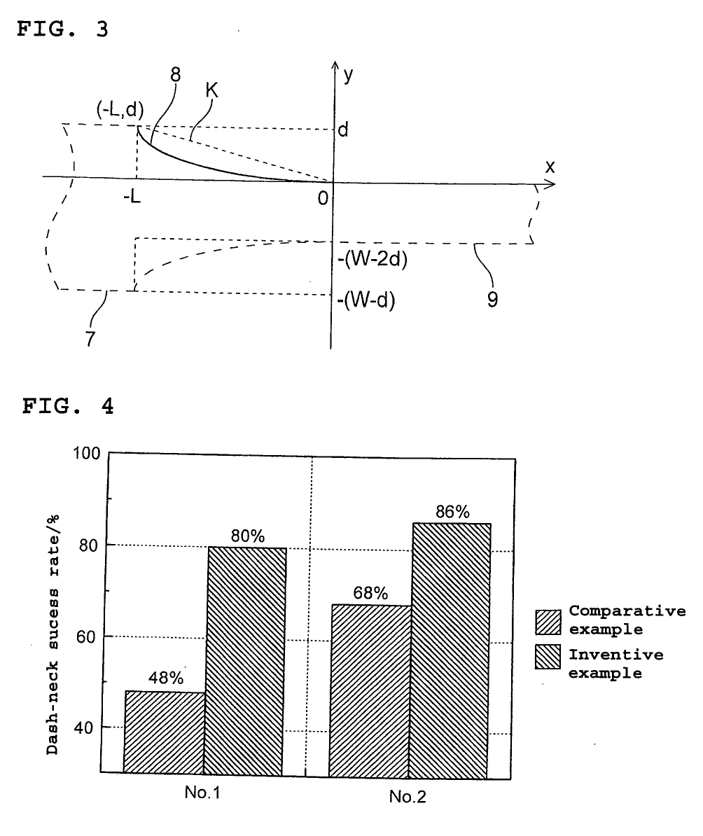

FIG. 4 is a diagram indicating the results of pulling tests in Example 1. Inventive Example in the figure is the case of a contour shape of the narrowed portion specified by the present invention and specifically shows the results in the case when a silicon single crystal formed using the parabola shown by equation (3) was pulled in the conditions of shape A indicated in Table 1.

Comparative Example indicates the results of the case when a silicon single crystal was pulled that was formed such that the contour of the narrowed portion was in agreement with the straight line connecting the contour of the lower end of the seed crystal to the contour of the upper end of the neck portion in the conditions of shape D indicated in Table 1 above.

The effect of the contour shape of the narrowed portion on dislocation elimination was evaluated by means of “Dash-neck success rate.” Here, “Dash-neck success rate” indicates the ratio of the pulling number of crystals that can avoid to become rich in dislocation until the completion of pulling of a silicon single crystal to the number of crystals that become rich in dislocation in which the constant diameter portion (body portion) length exceeds 300 mm even with dislocations, when the above contour of the narrowed portion is formed.

FIG. 4 shows that, even in both pulling apparatuses, Inventive Example with a contour shape of the narrowed portion specified by the present invention is high in Dash-neck success rate and excellent in the effect of the contour shape of the narrowed portion on dislocation elimination as compared with Comparative Example.

### Example 2

In Example 2, the situations of dislocation elimination in the neck portion were observed using Inventive Example and Comparative Example similar to Example 1.

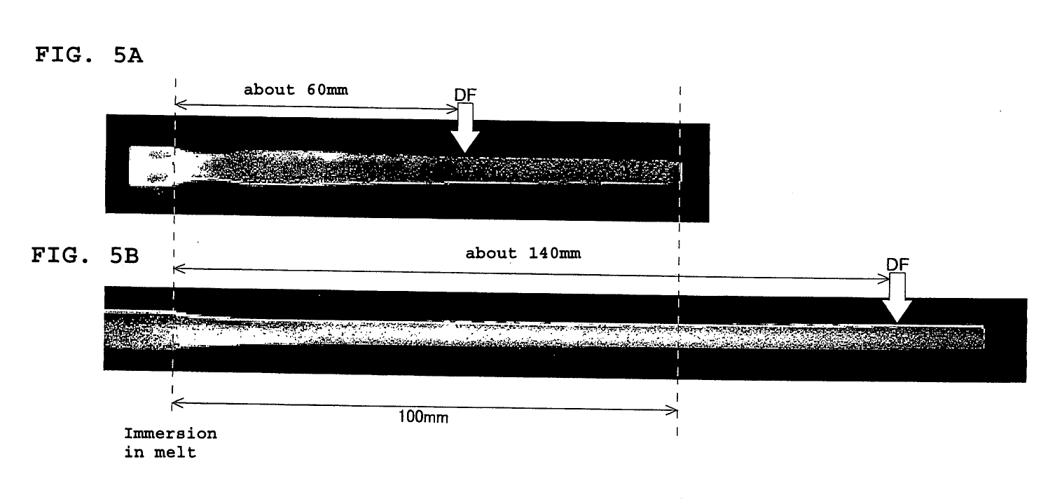

FIGS. 5A and 5B are diagrams indicating the observation results using X-ray topographs (XRT) in which the narrowed portion was vertically split and the behavior of the dislocations was observed: FIG. 5A indicates the result of Inventive Example; and FIG. 5B indicates the result of Comparative Example. In FIGS. 5A and 5B, the pulling direction is set to the left direction of the plane of the figure for convenience sake.

In FIGS. 5A and 5B, the position indicated by “immersion in melt” is a position at which a seed crystal was immersed in the silicon melt, and the seed crystal was pulled from the position and seed narrowing in which the narrowed portion and the neck portion are formed was carried out. The position shown with a down arrow with the symbol DF indicates a position at which a dislocation was determined to be completely removed by XRT testing.

As shown in the observation results in FIGS. 5A and 5B, the pulling length needed from the immersion in melt to the dislocation removal was about 60 mm in this Example, while it was about 140 mm in Comparative Example. These observation results show that the dislocations are removed in a pulling length ratio by as small as about 57% ({140 mm-60 mm}/140 mm) as compared with that of Comparative Example if a silicon single crystal with the contour shape of the narrowed portion specified in the present invention is used.

The above-described Example 2 indicated the case where the contour of the narrowed portion is a parabola expressed by equation (3) above. Further, a similar result is confirmed to be obtained even in the case when pulling testing as in Example 1 was performed and when the contour of the narrowed portion was formed using a circular arc expressed by equation (4) above or an elliptic arc expressed by equation (5) above.

In addition, the present invention is not limited to the above described embodiments, and a variety of modifications are possible within the scope of not departing the gist of the invention.

As described above, according to the silicon single crystal and its manufacturing method of the present invention, dislocations can be removed from the neck portion with a high success rate, a required time for pulling a silicon single crystal can be shorten, and the dislocation-free ratio can be improved during production of a silicon single crystal without lengthening the narrowed portion and the neck portion.

As a result, according to the silicon single crystal and its manufacturing method of the present invention, the productivity of a silicon single crystal can be improved, and the likelihood of dropping off of a silicon single crystal can be reduced, which can also improve the productivity of a silicon single crystal. Therefore, the present invention is an extremely useful technique in the field of the semiconductor substrate materials.

What is claimed is:

1. A silicon single crystal comprising: a seed crystal; a narrowed portion being provided at the lower end of the seed crystal and decreasing in diameter with distance from the seed crystal; a neck portion provided at the lower end of said narrowed portion; and a shoulder at the lower end of said neck portion,
wherein, in a front projection view, the contour of said narrowed portion is provided inside the straight line that connects the contour of the lower end of said seed crystal to the contour of the upper end of said neck portion and the contour of said neck portion is made to be a tangent at the lower end of said narrowed portion.

2. The silicon single crystal according to claim 1, wherein, in the contour of said narrowed portion in a front projection view, the length L of said narrowed portion in a pulling direction and the difference d between the radius of said seed crystal and the radius of the lower end of said narrowed portion satisfy equations (1) and (2) as below in terms of the diameter W of said seed crystal:
L/W≦2.5 (1)
d/W 24 0.156 (2)

3. The silicon single crystal according to claim 1, wherein the contour of said narrowed portion is formed with a parabola and expressed by equation (3)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of a said narrowed portion makes contact to said neck portion is set to be the center of coordinates:
y=ax² (a=d/L², −L≦x≦0, 0≦y≦d) (3)

4. The silicon single crystal according to claim 2, wherein the contour of said narrowed portion is formed with a parabola and expressed by equation (3)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of the narrowed portion to said neck portion is set to be the center of coordinates:
y=ax² (a=d/L², −L≦x≦0, 0≦y≦d) (3)

5. The silicon single crystal according to claim 1, wherein the contour of the narrowed portion is formed with a circular arc and expressed by equation (4)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of said narrowed portion to said neck portion is set to be the center of coordinates:
x²/b²+(y−b)²/b²=1 (b=(L²+d²)/2d, −L≦x≦0, 0≦y≦d) (4)

6. The silicon single crystal according to claim 2, wherein the contour of said narrowed portion is formed with a circular arc and expressed by equation (4)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of said narrowed portion to said neck portion is set to be the center of coordinates:
x²/b²+(y−b)²/b²=1 (b=(L²+d²)/2d, −L≦x≦0, 0≦y≦d) (4)

7. The silicon single crystal according to claim 1, wherein the contour of the narrowed portion is formed with an elliptic arc and expressed by equation (5)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of said narrowed portion to said neck portion is set to be the center of coordinates:
x²/p²+(y−q)²/q²=1 (L²/p²+(d−q)/²/q²=1, p≧L, q≧d, −L≦x≦0, 0≦y≦d) (5)

8. The silicon single crystal according to claim 2, wherein the contour of the narrowed portion is formed with an elliptic arc and expressed by equation (5)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of said narrowed portion to said the neck portion is set to be the center of coordinates:
x²/p²+(y−q)²/q²=1 (L²/p²+(d−q)²/q²=1, p≧L, q≧d, −L≦x≦0, 0≦y≦d) (5)

9. A method of producing a silicon single crystal in which a seed crystal is made contact with a melt of silicon raw materials and pulled, comprising the steps of:
forming a narrowed portion at the lower end of said seed crystal, the narrowed portion decreasing in diameter with distance from said seed crystal, forming a neck portion at the lower end of said narrowed portion, and
forming a shoulder at the lower end of said neck portion,
wherein, during the step of forming said narrowed portion, in a front projection view, the contour of said narrowed portion is provided inside the straight line that connects the contour of the lower end of said seed crystal to the contour of the upper end of said neck portion, and, at the lower end of said narrowed portion, the tangent of the contour of said narrowed portion constitutes the contour of said neck portion.

10. The method of producing a silicon single crystal according to claim 9, wherein, in the contour of said narrowed portion in a front projection view, the length L of said narrowed portion in a pulling direction and the difference d between the radius of said seed crystal and the radius of the lower end of said narrowed portion satisfy equations (1) and (2)as below in terms of the diameter W of said seed crystal.
L/W≦2.5 (1)
d/W≧0.156 (2)

11. The method of producing a silicon single crystal according to claim 9, wherein the contour of said narrowed portion is formed with a parabola and expressed by equation (3) as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at said narrowed portion to said neck portion is set to be the center of coordinates.
y=ax² (a=d/L², −L≦x≦0, 0≦y≦d) (3)

12. The method of producing a silicon single crystal according to claim 10, wherein the contour of the narrowed portion is formed with a parabola and expressed by equation (3)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of said narrowed portion to said neck portion is set to be the center of coordinates:
y=ax (a=d/L², −L≦x≦0, 0≦y≦d) (3)

13. The method of producing a silicon single crystal according to claim 9, wherein the contour of said narrowed portion is formed with a circular arc and expressed by equation (4)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and th point of tangency at the contour of said narrowed portion to said neck portion is set to be the center of coordinates:
x²/b²+(y−b)²/b²=1 (b=(L²+d²)/2d, −L≦x≦0, 0≦y≦d) (4)

14. The method of producing a silicon single crystal according to claim 10, wherein the contour of said narrowed portion is formed with a circular arc and expressed by equation (4)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of said narrowed portion to said neck portion is set to be the center of coordinates:
x²/b²+(y−b)²/b²=1 (b=(L²+d²)/2d, −L≦x≦0, 0≦y≦d) (4)

15. The method of producing a silicon single crystal according to claim 9, wherein the contour of said narrowed portion is formed with an elliptic arc and expressed by equation (5) as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of said narrowed portion to said neck portion is set to be the center of coordinates:
x²/p²+(y−q)²/q²=1 (L²/p²+(d−q)²/q²=1, p≧L, q≧d, −L≦x≦0, 0≦y≦d) (5)

16. The method of producing a silicon single crystal according to claim 10, wherein the contour of said narrowed portion is formed with an elliptic arc and expressed by equation (5)as below, where, in a front projection view, the direction from said seed crystal toward said narrowed portion and said neck portion is set to be a positive direction of x axis, the direction perpendicular to x axis and toward the surface from the centerline of said neck portion is set to be a positive direction of y axis and the point of tangency at the contour of said narrowed portion to said neck portion is set to be the center of coordinates:
x²/p²+(y−q)²/q²=1(L²/p²+(d−q)²/q²=1, p≧L, q≧d, −L≦x≦0, 0≦y≦d) (5)
